(19) United States
(12) Patent Application Publication
(10) Pub. No.: US 2008/0171449 A1
(43) Pub. Date: Jul. 17, 2008

(54) METHOD FOR CLEANING SALICIDE

(76) Inventors: Chao-Ching Hsieh, Tai-Nan City (TW); Tzung-Yu Hung, Tainan Hsien (TW); Chun-Chieh Chang, Tainan County (TW); Yi-Wei Chen, Tai-Chung Hsien (TW); Yu-Lan Chang, Kao-Hsiung City (TW)

Correspondence Address: NORTH AMERICA INTELLECTUAL PROPERTY CORPORATION, P.O. BOX 506, MERRIFIELD, VA, 22116, US

(21) Appl. No.: 11/623,099

(22) Filed: Jan. 15, 2007

(51) Int. Cl. H01L 21/335; H01L 21/8232

(52) U.S. Cl. 438/906; 438/142

(57) ABSTRACT

A method for cleaning suicide includes providing a substrate having at least an intergraded silicide and residues, sequentially performing an ammonia hydrogen peroxide (APM) mixture cleaning process and a vaporized hydrochloric acid-hydrogen peroxide mixture (HPM) cleaning process to remove the residues, and performing a sulfuric acid-hydrogen peroxide mixture (SPM) cleaning process to remove residuals of the vaporized HPM cleaning process.

### BACKGROUND OF THE INVENTION

1. Field of the Invention

The present invention relates to methods for cleaning self-aligned silicidation (salicide), and more particularly, to methods for cleaning salicide capable of preventing the salicide from further contamination.

2. Description of the Prior Art

In semiconductor manufacturing processes, a wafer undergoes several deposition, photolithography, etching, and transporting processes to obtain designed integrated circuit patterns. Therefore a great deal of particles, such as metals, inorganics, and organics, together with native oxide or other contaminants generated by artificial or environmental factors remain on, and contaminate the wafer. Thus, for maintaining the surface cleanliness of the wafer and improving reliability and yield of the wafer, a variety of cleaning methods are conducted in the manufacturing processes.

Please refer to FIGS. 1-2, which are drawings illustrating a conventional method for forming salicide. As shown in FIG. 1, a wafer 10 having a substrate 12 and a transistor 14 formed thereon is provided. The transistor 14 comprises a gate dielectric layer 16, a gate 18, and lightly doped drains (LDDs) 20 formed in the substrate 12 adjacent to two sides of the gate 18, spacers 22 formed on sidewalls of the gate 18, and a source/drain 24. The salicide is formed after forming the source/drain 24. A metal layer such as a nickel layer 26 and a TiN layer 28 are deposited on the substrate 12 by thin film deposition. Please refer to FIG. 2. Then, a first rapid thermal process (RTP) is performed to make parts of the nickel layer 26 react with silicon of the gate 18 and the source/drain 24 underneath and form intergraded salicide 30. Following the first RTP, an SPM cleaning process is performed to remove the TiN layer 28 and unreacted nickel. A second RTP is then performed to transform the intergraded salicide into salicide having a lower resistance.

In the conventional salicide process, a metal such as platinum (Pt) is added with a low concentration ranging from 3-8% to the nickel layer 26 to prevent nickel silicide (NiSi) from agglomeration, which causes junction leakage, during the first RTP. The added Pt improves thermal stability of the NiSi and prevents agglomeration at a relatively higher temperature. To remove the added Pt, an HPM cleaning process is added after the SPM cleaning process to remove the unreacted Pt. The added HPM reacts with the unreacted Pt above the intergraded silicide 30 to form soluble complex ions.

It should be noted that the HPM, which comprises hydrogen peroxide, vaporized hydrochloric acid, and vaporized chlorine often damages the intergraded salicide 30, and even erodes and strips the intergraded salicide 30. Chloride ions and hydrochloric acid of the HPM may react with the remaining agents of the former processes and form salts. The salts remaining on the surface of the wafer and in the wet bench are harmful to the surface cleanliness and cause contamination in the wet bench. In addition, the extremely corrosive and toxic HPM pollutes the environment and endangers operators.

Therefore, a method that can effectively remove residuals of the HPM cleaning process, improve surface cleanliness of the wafer, and further prevent the cleaned wafer from further contamination is still needed.

### SUMMARY OF THE INVENTION

Therefore the present invention provides methods for cleaning salicide for preventing surface cleanliness of the wafer from being influenced by the second contamination.

According to the claimed invention, a method for cleaning salicide is provided. The method comprises providing a substrate having at least an intergraded silicide and residues formed thereon, performing an ammonia hydrogen peroxide mixture (APM) cleaning process to clean the substrate, performing a vaporized hydrochloric acid-hydrogen peroxide mixture (HPM) cleaning process to clean the substrate again, and performing a sulfuric acid-hydrogen peroxide mixture (SPM) cleaning process to remove residuals of the vaporized HPM cleaning process.

According to the claimed invention, another method for cleaning salicide is provided. The method comprises providing a substrate having at least an intergraded silicide and remnant metals formed thereon, performing an vaporized HPM cleaning process to remove the remnant metals from the substrate, and performing an SPM cleaning process to remove residuals of the vaporized HPM cleaning process.

According to the claimed invention, a wet cleaning process is provided. The method comprises performing a vaporized HPM cleaning process, and performing an SPM cleaning process to remove residuals of the vaporized HPM cleaning process.

According to the present invention, the SPM cleaning process is added after the vaporized HPM cleaning process, the active residuals of the vaporized HPM will be completely removed from the wafer in the SPM cleaning process, therefore the surface cleanliness of the wafer is improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-2 are drawings illustrating a conventional method for forming salicide.

FIGS. 3-5 are drawings illustrating a first preferred embodiment provided by the present invention.

FIG. 6 is a drawing illustrating remaining particle amounts on a cleaned wafer according to the first preferred embodiment.

FIG. 7 is a drawing illustrating a second preferred embodiment provided by the present invention.

FIG. 8 is a drawing illustrating remaining particle amounts on a cleaned wafer according to the second preferred embodiment.

FIG. 9 is a drawing illustrating steps for forming a salicide.

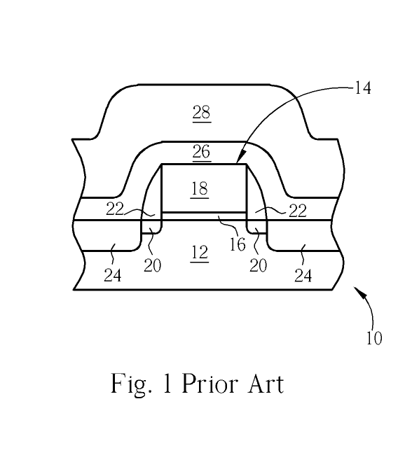

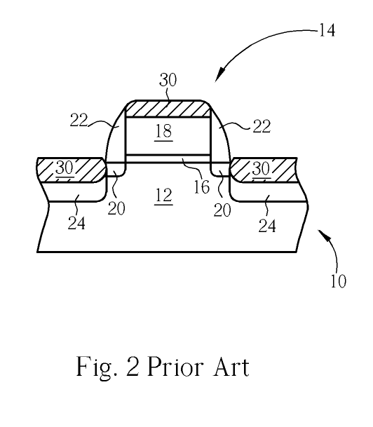

### DETAILED DESCRIPTION

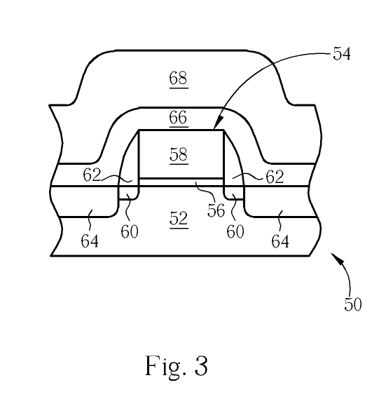

Please refer to FIGS. 3-5, which are drawings illustrating a first preferred embodiment provided by the present invention. As shown in FIG. 3, a wafer 50 having a substrate 52 is provided. The substrate 52 has completely undergone a shallow trench isolation (STI) process and a well formation process, and at least a transistor 54 having a gate dielectric layer 56 and a gate 58 is formed in the substrate 52. The gate dielectric layer 56 comprises a nitric oxide layer, a nitride layer, an oxide layer, or another dielectric layer; the gate 58 comprises conductive material such as doped polycrystalline silicon. The transistor 54 also comprises lightly doped drains (LDDs) 60 formed in the substrate 52 adjacent to two sides of the gate 58, spacers 62 formed on sidewalls of the gate 58, and a source/drain 64 formed in the substrate 52 adjacent to the spacers 62.

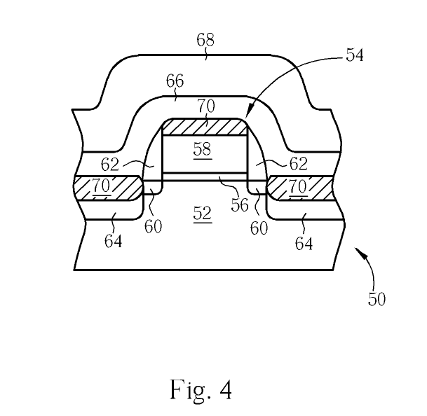

Please refer to FIGS. 3-4. A thin film deposition process is performed to form a metal layer 66 and a TiN layer 68 used as a barrier layer on the substrate 52 and the transistor 54. The metal layer 66 comprises a first metal comprising platinum (Pt), nickel (Ni), cobalt (Co), titanium (Ti) or alloys of the aforementioned metals used to form silicide and, a second metal comprising Pt, Co, palladium (Pd), manganese (Mn), tantalum (Ta), ruthenium (Ru) or alloys of the aforementioned metals in a low concentration. The second metal is in a concentration of 3-8% (wt %) and is used to improve a thermal stability of the salicide and to prevent the salicide from agglomeration which increases contact resistance and junction leakage. In the first preferred embodiment, the first metal is Ni and the second metal is Pt. However, in a modification of the first preferred embodiment, the first metal is not limited to Ni, but can be Co or Pt; and, the second metal used to improve thermal stability is not limited to Pt, but can also be Pd, Mo, Ta, or Ru. Then, a first rapid thermal process (RTP) is performed to make the nickel layer 66 react with silicon of the gate 58 and the source/drain 64 and to form intergraded salicides 70. These processes are well known to those skilled in the art and further detailed description is therefore omitted here for brevity.

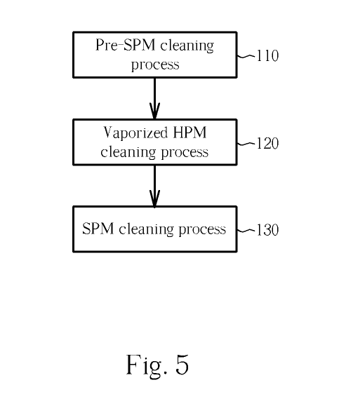

Please refer to FIG. 5. For removing unreacted Ni and other residues, the wafer 50 is positioned in a wet cleaning apparatus and undergoes a vaporized HPM cleaning process 120 for a duration of 4-5 minutes to remove residues such as remnant metals: Pt, Co, Pd, Mn, Ta, Ru, or alloys of the aforementioned metals from the wafer 50. In addition, as shown in FIG. 5, to further remove the residues, a pre-SPM cleaning process 110 is added before performing the vaporized HPM cleaning process 120.

Please refer to FIG. 5 again. To remove the residuals of the vaporized HPM cleaning process 120, the wafer undergoes an SPM cleaning process 130 in the wet cleaning apparatus. The SPM cleaning process 130 is performed at a temperature between 95-120° C. for a duration of 4-5 minutes. It is noteworthy that the SPM cleaning processes 130 are performed after the vaporized HPM cleaning processes 120 to remove residuals, such as chlorine, hydrochloric acid, and salts from the wafer 50 and to improve surface cleanliness of the wafer 50.

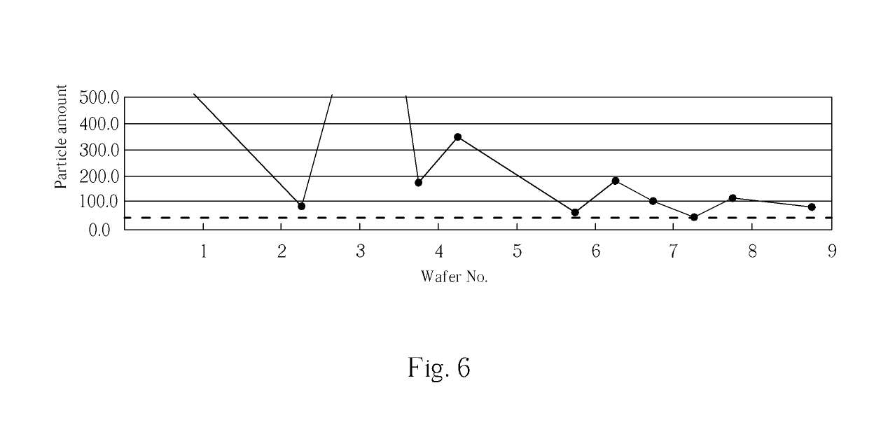

Please refer to FIG. 6 which is a drawing illustrating remaining particle amounts on the cleaned wafer according to the first embodiment provided by the present invention. As shown in FIG. 6, the remaining particles on the cleaned wafer 50 are reduced to under 40. Therefore, the method for cleaning salicide provided by the first preferred embodiment indeed improves surface cleanliness of the wafer.

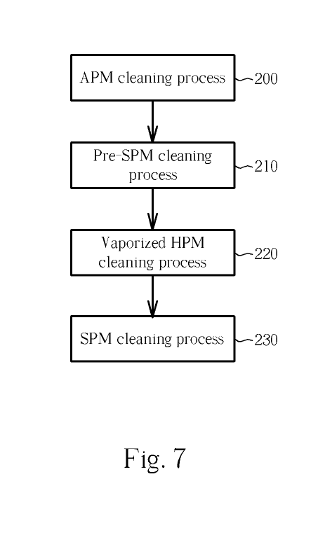

Please refer to FIG. 7, which is a drawing illustrating a second preferred embodiment provided by the present invention. As shown in FIG. 7, for removing the unreacted Ni and other residues from the intergraded salicide 70, the wafer 50 is positioned in a wet cleaning apparatus. Then, an APM cleaning process 200 is performed at a temperature between 30-70° C. to remove residues from the substrate 52. Following the APM cleaning process 200, an vaporized HPM cleaning process 220 is performed for a duration of 4-5 minutes to remove residues such as remnant metals: Pt, Co, Pd, Mn, Ta, Ru, or alloys of the aforementioned metals. In addition, as shown in FIG. 7, for further removing the remnant metals such as Pt or Co, a pre-SPM cleaning process 210 is added before the vaporized HPM cleaning process 220.

Please refer to FIG. 7 again. For removing residuals of the vaporized HPM cleaning process 220, an SPM cleaning process 230 is performed in the wet cleaning apparatus. The SPM cleaning process 230 is performed at a temperature between 90-120° C. for a duration of 4-5 minutes. Please note that the SPM cleaning processes 230 are performed after the vaporized HPM cleaning processes 220 to remove residuals, such as chlorine, hydrochloric acid, and salts from the wafer 50 and to improve surface cleanliness of the wafer 50.

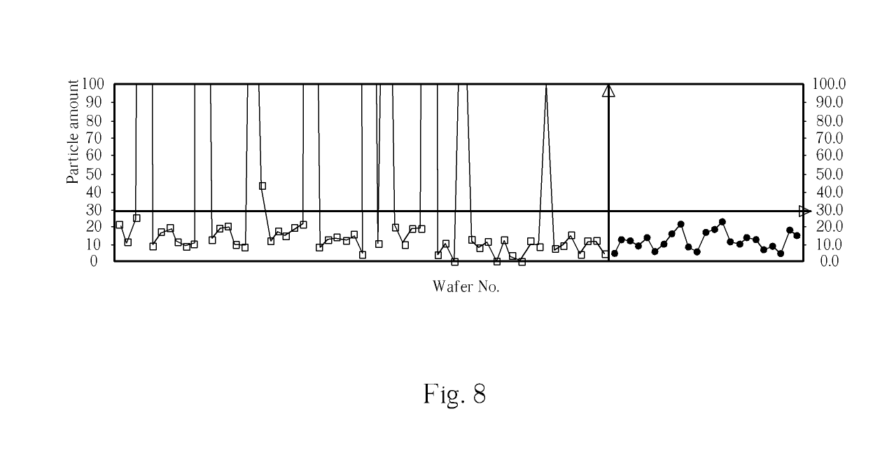

Please refer to FIG. 8, which is a drawing illustrating remaining particle amounts on the cleaned wafer. As shown in FIG. 8, the remaining particles on the cleaned wafer 50 are reduced to 20, which is much lower than the desired standard of 30. Therefore, the method for cleaning salicide provided by the second preferred embodiment indeed improves surface cleanliness of the wafer.

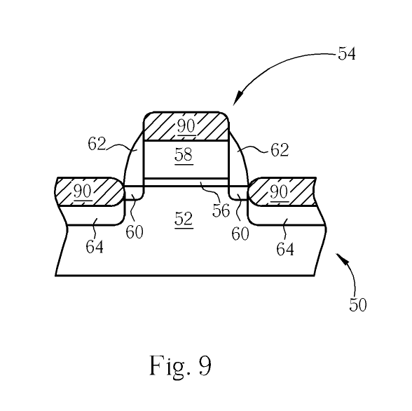

Please refer to FIG. 9 which is a drawing illustrating steps for forming the salicide. As shown in FIG. 9, a second RTP is performed on the wafer 50 to transform the intergraded salicides 70 into salicides 90. The salicides 90 can be nickel salicide, cobalt salicide, titanium salicide, or a combination of the aforementioned metals. For example, in the first and second preferred embodiments, the salicide comprises nickel salicide.

According to the first and second preferred embodiments provided by the present invention, the SPM cleaning processes 130, 230 are performed after the vaporized HPM cleaning processes 120, 220 to remove residuals, such as chlorine, hydrochloric acid, and salts to improve surface cleanliness of the wafer 50.

As mentioned above, the present invention actually provides a wet cleaning method which can be applied to a method for cleaning salicide. Because hydrogen peroxide, hydrochloric acid, and chlorine used in the vaporized HPM cleaning process are vaporized and often remain on the cleaning objects and in the wet cleaning apparatus, even reacting with agents used in preceding processes and forming salts. Those particles and residuals remaining on the object will contaminate the wafer again. Therefore, an SPM cleaning process is performed after the vaporized HPM cleaning process at a temperature between 90-120° C. for a duration of 4-5 minutes to remove those residuals. Furthermore, the SPM cleaning process and the vaporized HPM cleaning process are performed in the same wet cleaning apparatus.

When the wet cleaning method provided by the invention is applied to a method for cleaning salicide, the SPM cleaning process added after the vaporized HPM cleaning process will remove the active residuals of the vaporized HPM process from the wafer, therefore surface cleanliness of the wafer is improved and the pollution to the environment and danger to the operator are reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for cleaning salicide comprising steps of:
providing a substrate having at least an intergraded silicide and residues formed thereon;
performing an ammonia hydrogen peroxide mixture (APM) cleaning process to clean the substrate;
performing a vaporized hydrochloric acid-hydrogen peroxide mixture (HPM) cleaning process to clean the substrate again; and
performing a sulfuric acid-hydrogen peroxide mixture (SPM) cleaning process to clean residuals of the vaporized HPM cleaning process.

2. The method of claim 1, wherein the APM cleaning process is used to remove the residues from the substrate.

3. The method of claim 1, wherein the APM cleaning process is performed at a temperature between 30-70° C.

4. The method of claim 1 further comprising a step of performing a pre-SPM cleaning process after the APM cleaning process.

5. The method of claim 4, wherein the pre-SPM cleaning process is used to remove the residues from the substrate.

6. The method of claim 1, wherein the vaporized HPM cleaning process is used to remove the residues from the substrate.

7. The method of claim 6, wherein the residues comprise platinum (Pt), cobalt (Co), palladium (Pd), manganese (Mn), tantalum (Ta), ruthenium (Ru) or alloys of the aforementioned metals.

8. The method of claim 1, wherein the HPM comprises vaporized hydrogen peroxide, hydrochloric acid, and chlorine.

9. The method of claim 1, wherein the vaporized HPM cleaning process is performed for 4-5 minutes.

10. The method of claim 1, wherein the SPM cleaning process is performed at a temperature between 95-120° C.

11. The method of claim 1, wherein the SPM cleaning process is performed for 4-5 minutes.

12. The method of claim 1, wherein the APM cleaning process, the vaporized HPM cleaning process, and the SPM cleaning process are performed in a same wet cleaning apparatus.

13. The method of claim 1 further comprising steps for forming the intergraded silicide of:
forming a gate structure and a source/drain in the substrate adjacent to two sides of the gate structure;
forming a metal layer on the substrate;
forming a TiN layer on the metal layer; and
performing a first rapid thermal process (RTP) to form the intergraded silicide on the gate structure and the source/drain.

14. The method of claim 13, further comprising a step of performing a second RTP after the SPM cleaning process to transform the intergraded silicide into silicide.

15. The method of claim 14, wherein the silicide comprises nickel silicide, cobalt silicide, titanium silicide or a combination thereof.

16. A method for cleaning salicide comprising steps of:
providing a substrate having at least an intergraded silicide and remnant metals formed thereon;
performing a vaporized hydrochloric acid-hydrogen peroxide mixture (HPM) cleaning process to remove the remnant metal from the substrate; and
performing a sulfuric acid-hydrogen peroxide mixture (SPM) cleaning process to clean residuals of the vaporized HPM cleaning process.

17. The method of claim 16, wherein the remnant metals comprise platinum (Pt), cobalt (Co), palladium (Pd), manganese (Mn), tantalum (Ta), ruthenium (Ru) or alloys of the aforementioned metals.

18. The method of claim 16, wherein the HPM comprises vaporized hydrogen peroxide, hydrochloric acid, and chlorine.

19. The method of claim 16, wherein the vaporized HPM cleaning process is performed for 4-5 minutes.

20. The method of claim 16, wherein the SPM cleaning process is performed at a temperature between 95-120° C.

21. The method of claim 16, wherein the SPM cleaning process is performed for 4-5 minutes.

22. The method of claim 16, wherein the vaporized HPM cleaning process and the SPM cleaning process are performed in a same wet cleaning apparatus.

23. The method of claim 16 further comprising steps for forming the intergraded silicide of:
forming a gate structure and a source/drain in the substrate adjacent to two sides of the gate structure;
forming a metal layer on the substrate;
forming a TiN layer on the metal layer; and
performing a first rapid thermal process (RTP) to form the intergraded silicide on the gate structure and the source/drain.

24. A wet cleaning process comprising steps of:
performing a vaporized hydrochloric acid-hydrogen peroxide mixture (HPM) cleaning process; and
performing a sulfuric acid-hydrogen peroxide mixture (SPM) cleaning process to clean residuals of the vaporized HPM cleaning process.

25. The method of claim 24, wherein the HPM comprises vaporized hydrogen peroxide, hydrochloric acid, and chlorine.

26. The method of claim 24, wherein the vaporized HPM cleaning process is performed for 4-5 minutes.

27. The method of claim 24, wherein the SPM cleaning process is performed at a temperature between 95-120° C.

28. The method of claim 24, wherein the SPM cleaning process is performed for 4-5 minutes.

29. The method of claim 24, wherein the vaporized HPM cleaning process and the SPM cleaning process are performed in a same wet cleaning apparatus.
